(19) United States
(12) Patent Application Publication
(10) Pub. No.: US 2024/0027699 A1
(43) Pub. Date: Jan. 25, 2024

(54) TECHNOLOGIES FOR A BEAM EXPANSION IN GLASS SUBSTRATES

(71) Applicant: Intel Corporation, Santa Clara, CA (US)

(72) Inventors: Nicholas D. Psaila, Lanark (GB); Pooya Tadayon, Portland, OR (US)

(73) Assignee: Intel Corporation, Santa Clara, CA (US)

(21) Appl. No.: 17/869,372

(22) Filed: Jul. 20, 2022

(51) Int. Cl. G02B 6/42

(52) U.S. Cl. CPC G02B 6/4214; G02B 6/4278; G02B 6/4244; G02B 6/4245; G02B 27/30

(57) ABSTRACT

Technologies for beam expansion in glass substrates are disclosed. In the illustrative embodiment, light in a waveguide defined in a glass substrate is allowed to expand towards a curved mirror defined in the glass substrate. The light is collimated to a beam as it is reflected off the mirror. In the illustrative embodiment, the light is reflected upwards toward the top surface of the glass substrate. A photonic integrated circuit (PIC) die may be mounted on the glass substrate. A micromirror lens fixed to the PIC die can focus the collimated beam into a waveguide defined in the PIC die. In some embodiments, an interface for an optical connector may be formed in the glass substrate, allowing the optical connector to be removably plugged into the glass substrate.

### BACKGROUND

Photonic integrated circuits (PICs) can be used for several applications, such as communications. Efficiently and cheaply aligning optics to couple light into and out of PICs can be a challenge. Approaches such as attachment of optical fiber arrays to PICs may be slow, incompatible with conventional semiconductor packaging processes, and can result in substantial yield and throughput issues.

### BRIEF DESCRIPTION OF THE DRAWINGS

FIG. 1 is an isometric view of a system including a glass substrate with a photonic integrated circuit (PIC) die and an electrical integrated circuit (EIC) die mounted on it.

FIG. 2 is a top-down view of the system of FIG. 1.

FIG. 3 is a cross-sectional view of one embodiment of the system of FIG. 1.

FIG. 4 is a cross-sectional view of one embodiment of the system of FIG. 1.

FIG. 5 is a top-down view of one embodiment of the system of FIG. 1.

FIG. 6 is a cross-sectional view of one embodiment of the system of FIG. 5.

FIG. 7 depicts a plot showing coupling loss as a function of misalignment for different beam sizes.

FIG. 8 depicts a plot showing beam diameter as a function of beam position.

FIG. 9 is a cross-sectional view of one embodiment of a system including a glass substrate with two PIC dies mounted on it.

FIGS. 10 and 11 are a simplified flow diagram of at least one embodiment of a method for manufacturing a system including a glass substrate with a PIC die and an EIC die mounted on it.

FIG. 12 is a top view of a wafer and dies that may be included in a microelectronic assembly, in accordance with any of the embodiments disclosed herein.

FIG. 13 is a cross-sectional side view of an integrated circuit device that may be included in a microelectronic assembly, in accordance with any of the embodiments disclosed herein.

FIGS. 14A-14D are perspective views of example planar, gate-all-around, and stacked gate-all-around transistors.

FIG. 15 is a cross-sectional side view of an integrated circuit device assembly that may include a microelectronic assembly, in accordance with any of the embodiments disclosed herein.

FIG. 16 is a block diagram of an example electrical device that may include a microelectronic assembly, in accordance with any of the embodiments disclosed herein.

### DETAILED DESCRIPTION

In various embodiments disclosed herein, a glass substrate can be created with one or more waveguides and one or more micromirrors in the glass substrate. An optical connector can mate with the glass substrate, connecting optical fibers to the waveguides defined in the glass substrate. The waveguides in the glass substrate can terminate, allowing the light from the waveguides to expand. The micromirrors in the glass substrate can both collimate the light and reflect the light towards the top of the glass substrate. A photonic integrated circuit (PIC) die may be positioned on top of the glass substrate. Mirrors or lenses mounted to the PIC die can focus the light into waveguides defined in the PIC die. Electronic components such as one or more redistribution layers, through-glass vias, etc., can also be included on the glass substrate. In addition to one or more PIC dies, one or more electrical integrated circuit (EIC) dies may also be mounted on the glass substrate.

As used herein, the phrase “communicatively coupled” refers to the ability of a component to send a signal to or receive a signal from another component. The signal can be any type of signal, such as an input signal, an output signal, or a power signal. A component can send or receive a signal to another component to which it is communicatively coupled via a wired or wireless communication medium (e.g., conductive traces, conductive contacts, air). Examples of components that are communicatively coupled include integrated circuit dies located in the same package that communicate via an embedded bridge in a package substrate and an integrated circuit component attached to a printed circuit board that send signals to or receives signals from other integrated circuit components or electronic devices attached to the printed circuit board.

In the following description, specific details are set forth, but embodiments of the technologies described herein may be practiced without these specific details. Well-known circuits, structures, and techniques have not been shown in detail to avoid obscuring an understanding of this description. Phrases such as “an embodiment,” “various embodiments,” “some embodiments,” and the like may include features, structures, or characteristics, but not every embodiment necessarily includes the particular features, structures, or characteristics.

Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or any other manner. “Connected” may indicate elements are in direct physical or electrical contact, and “coupled” may indicate elements co-operate or interact, but they may or may not be in direct physical or electrical contact. Furthermore, the terms “comprising,” “including,” “having,” and the like, as used with respect to embodiments of the present disclosure, are synonymous. Terms modified by the word “substantially” include arrangements, orientations, spacings, or positions that vary slightly from the meaning of the unmodified term. For example, the central axis of a magnetic plug that is substantially coaxially aligned with a through hole may be misaligned from a central axis of the through hole by several degrees. In another example, a substrate assembly feature, such as a through width, that is described as having substantially a listed dimension can vary within a few percent of the listed dimension.

It will be understood that in the examples shown and described further below, the figures may not be drawn to scale and may not include all possible layers and/or circuit components. In addition, it will be understood that although certain figures illustrate transistor designs with source/drain regions, electrodes, etc. having orthogonal (e.g., perpendicular) boundaries, embodiments herein may implement such boundaries in a substantially orthogonal manner (e.g., within +/−5 or 10 degrees of orthogonality) due to fabrication methods used to create such devices or for other reasons.

Reference is now made to the drawings, which are not necessarily drawn to scale, wherein similar or same numbers may be used to designate the same or similar parts in different figures. The use of similar or same numbers in different figures does not mean all figures including similar or same numbers constitute a single or same embodiment. Like numerals having different letter suffixes may represent different instances of similar components. The drawings illustrate generally, by way of example, but not by way of limitation, various embodiments discussed in the present document.

In the following description, for purposes of explanation, numerous specific details are set forth in order to provide a thorough understanding thereof. It may be evident, however, that the novel embodiments can be practiced without these specific details. In other instances, well-known structures and devices are shown in block diagram form in order to facilitate a description thereof. The intention is to cover all modifications, equivalents, and alternatives within the scope of the claims.

As used herein, the phrase “located on” in the context of a first layer or component located on a second layer or component refers to the first layer or component being directly physically attached to the second part or component (no layers or components between the first and second layers or components) or physically attached to the second layer or component with one or more intervening layers or components.

As used herein, the term “adjacent” refers to layers or components that are in physical contact with each other. That is, there is no layer or component between the stated adjacent layers or components. For example, a layer X that is adjacent to a layer Y refers to a layer that is in physical contact with layer Y.

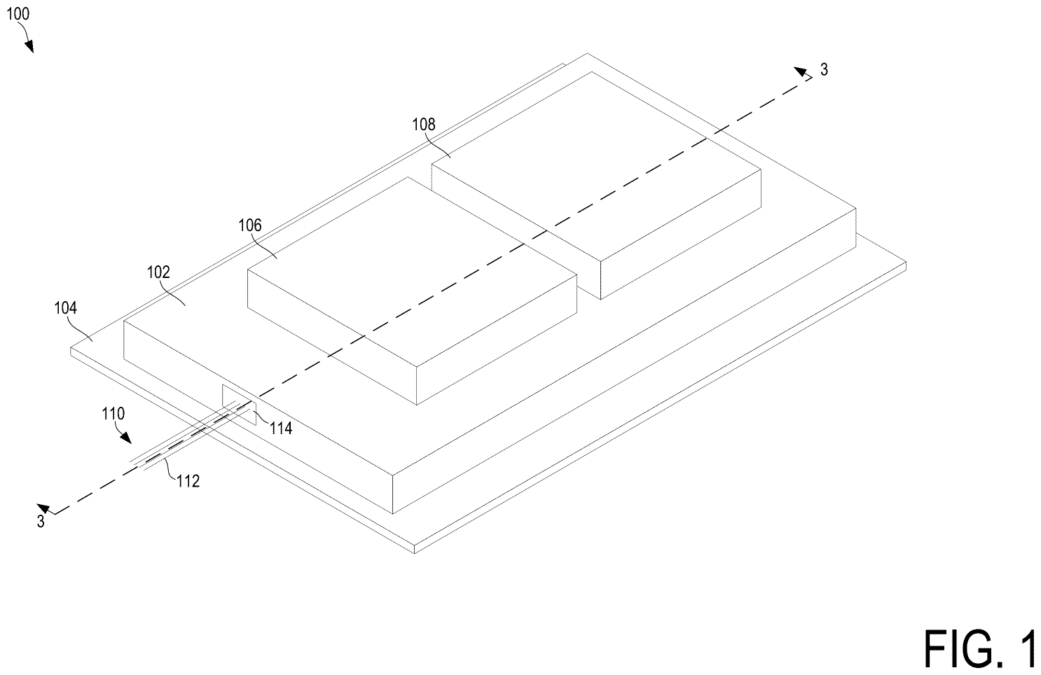

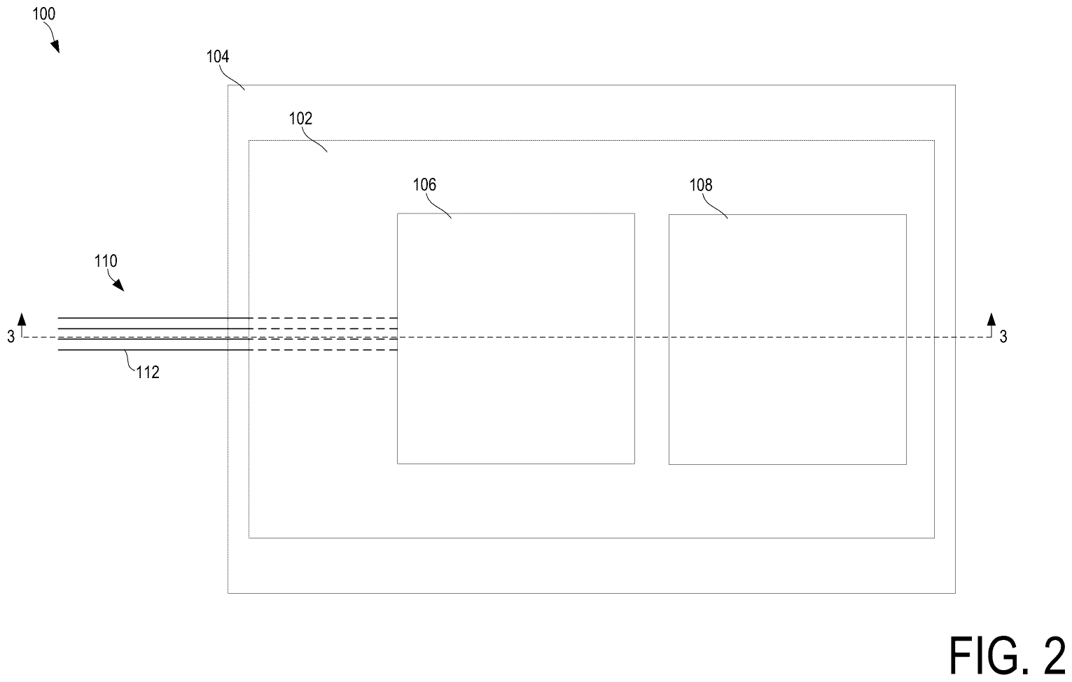

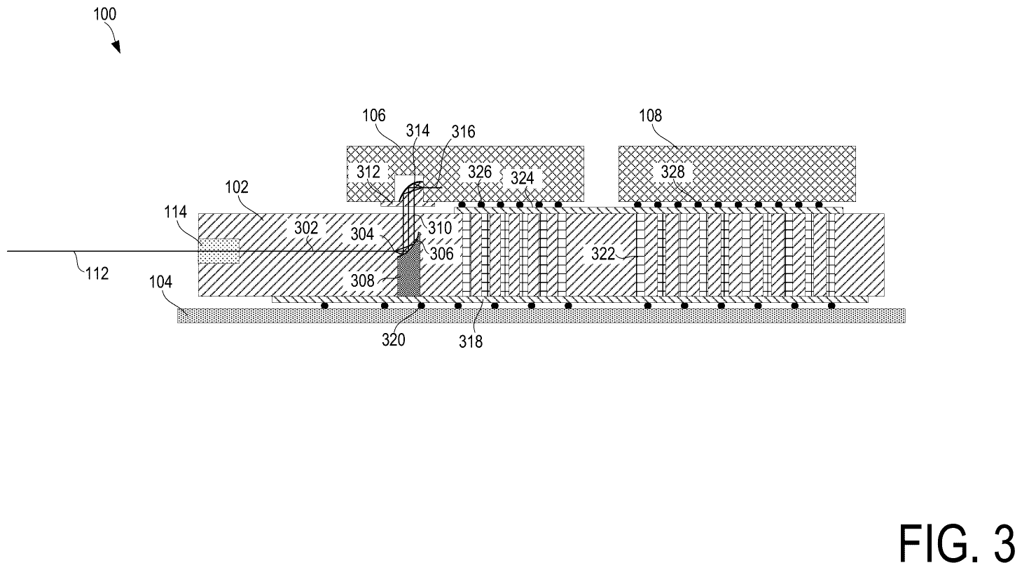

Referring now to FIGS. 1-3, in one embodiment, a system 100 includes a glass substrate 102 mounted on a circuit board 104. FIG. 1 shows a perspective view of the system 100, FIG. 2 shows a top-down view of the system 100, and FIG. 3 shows a cross-sectional view of one embodiment of the system 100. In an illustrative embodiment, a photonic integrated circuit (PIC) die 106 is mounted on the glass substrate 102. An electronic integrated circuit (EIC) die 108 may also be mounted on the glass substrate 102.

In the illustrative embodiment, an optical plug 114 is mated with the glass substrate 102. An array 110 of optical fibers 112 is connected to the optical plug 114. The optical fibers 112 are aligned to waveguides 302 defined in the glass substrate 102, as shown in FIG. 3. A waveguide 302 can transport light from an optical fiber 112 to a termination point 304 of the waveguide. At the termination point 304, the waveguide 302 stops guiding the light, allowing it to expand. The light expands to a curved micromirror 306 defined in the glass substrate 102. In the illustrative embodiment, the curved micromirror 306 is formed monolithically in the glass substrate 102. The curved micromirror 306 collimates the light into a collimated beam 310, and directs the beam 310 out of the top of the glass substrate 102.

In the illustrative embodiment, a glass insert 312 is positioned at least partially inside of a cavity defined in a bottom surface of the PIC die 106. The glass insert 312 includes a curved micromirror 314. The beam 310 is directed towards the micromirror 314, which focuses the light into a waveguide 316 defined in the PIC die 106. It should be appreciated that, as the diameter of the collimated beam 310 is significantly larger than the diameter of the beam in the waveguide 302 or waveguide 316, the alignment of the PIC die 106 to the glass substrate 102 is less sensitive than for, e.g., direct coupling between waveguides.

In the illustrative embodiment, the glass substrate 102 may also provide electrical connections. For example, the glass substrate 102 may include a redistribution layer 318 on the bottom of the substrate 102 and/or may include a redistribution layer 324 on the top of the substrate 102. Through-glass vias 322 filled with conductive material may provide electrical connections between the top and bottom surfaces of the glass substrate 102 (e.g., between the redistribution layer 318 and the redistribution layers 324). The redistribution layer 318 and/or the glass substrate 102 may be electrically and physically connected to the circuit board 104 through solder joints 320 or bumps 320. The solder joints 320 may provide signals and/or power to the glass substrate 102. Similarly, solder joints 326, 328 may electrically and physically connect the PIC die 106 and EIC die 108, respectively, to the glass substrate 102. The redistribution layers 318, 324 may be formed on or as part of the glass substrate 102. The redistribution layers 318, 324 may include one or more layers of traces or other electrical connections.

The illustrative circuit board 104 may be made from ceramic, glass, and/or organic-based materials with fiberglass and resin, such as FR-4. The circuit board 104 may have any suitable length or width, such as 10-500 millimeters. The circuit board 104 may have any suitable thickness, such as 0.2-5 millimeters. The circuit board 104 may support additional components besides the glass substrate 102, such as additional photonic or electronic integrated circuit components, a processor unit, a memory device, an accelerator device, etc.

The illustrative glass substrate 102 is silicon oxide glass. In other embodiments, the substrate 102 may be made of any suitable crystalline or non-crystalline material, such as fused silicon, borosilicate, sapphire, yttrium aluminum garnet, etc. The glass substrate 102 may have any suitable length or width, such as 10-500 millimeters. The glass substrate 102 may have any suitable thickness, such as 0.2-5 millimeters.

The glass substrate 102 may have an interface for any suitable optical connector 114, such as alignments pins to mate with an MT connector or MPO connector. In other embodiments, the glass substrate 102 may include mechanical features that allow a secondary connector receptacle piece to passively align and attach to the substrate 102. The optical connector 114 may include any suitable number of optical fibers 112, and the glass substrate 102 may include any suitable number of waveguides 302, such as 1-1,024 waveguides. The curved mirror 306 may be made of any suitable material, such as a reflective metal such as aluminum, silver, gold, etc. In some embodiments, the curved mirror 306 may be made of a dielectric stack. In other embodiments, the curved mirror 306 may operate based on total internal reflection. In the illustrative embodiment and as discussed in more detail below, the shape of the mirror 306 may be formed by selective laser etching to remove a section 308 from the bottom of the glass substrate 102. After the reflective surface of the mirror 306 is applied, the section 308 may be backfilled with any suitable material, allowing for planarization of the glass substrate 102. In the illustrative embodiment, the mirrors 306 direct the beams 310 out of the glass substrate 102 at approximately normal incidence. In other embodiments, the geometry of the mirrors 306 may be tailored to control the angle of the beam 310 emerging from the surface of the substrate 102, which may mitigate backreflections from the surface of the substrate 102 or may be used to control incident angles for achieving total internal reflection. In some embodiments, polarization filtering could also be achieved by appropriate geometries to make use of Brewster angles of incidence on the reflecting surfaces.

The glass substrate 102 may route the waveguides 302 in the glass substrate 102 in any suitable manner, including in three dimensions, allowing for flexible layouts. The glass substrate 102 may include optical elements such as fan outs, splitters, couplers, combiners, filters, etc. In some embodiments, the glass substrate 102 may include active optical elements, such as optical amplifiers, lasers, photodetectors, modulators, etc.

The light in the optical fibers 112 and waveguides 302, 316 may be any suitable wavelength, such as 400-2,000 nanometers. In the illustrative embodiment, the light in the optical fibers 112 and waveguides 302, 316 is, e.g., 1,200-1,600 nanometers. The mirror 306 may collimate the light to a beam 310 of any suitable diameter, such as 20-500 micrometers, as measured at the 1/e² width. The mirror 306 may have any suitable shape, such as an off-axis parabola, a toroidal surface, an aspherical surface, etc. In some embodiments, the mirrors 306 may be arranged in two-dimensional arrays to increase channel density.

The glass insert 312 may be made of any suitable material, such as glass, silicon, plastic, etc. The mirror 314 may be similar to the mirror 306. The trench in the PIC die 106 into which the mirror 314 extends may have any suitable dimensions, such as a depth of, e.g., 50 micrometers and width of e.g., 200 micrometers. In some embodiments, the mirror 314 may be monolithically formed as part of the substrate of the PIC die 106. In some embodiments, a collimated beam may be coupled to a waveguide 316 in the PIC die 106 without using a glass insert 312, such as by using backside etched lenses in combination with backside emitting grating couplers. More generally, any suitable optical element separate from or integrated into the PIC die 106 may be used to couple a collimated beam from the glass substrate 102 into waveguides 316 in the PIC die 106.

The PIC die 106 may be made of any suitable material, such as silicon. In the illustrative embodiment, the waveguides 316 may be silicon waveguides embedded in silicon oxide cladding. The PIC die 106 may include any suitable number of waveguides 316, such as 1-1,024. In the illustrative embodiment, the waveguides 316 in the PIC die 106 are edge-coupled waveguides 316. In other embodiments, the waveguides 316 may be vertically coupled out of the PIC die 106.

The PIC die 106 is configured to generate, detect, and/or manipulate light. The PIC die 106 may include active or passive optical elements such as splitters, couplers, filters, optical amplifiers, lasers, photodetectors, modulators, etc.

The EIC die 108 may include any suitable electronic integrated circuit component, such as resistors, capacitors, inductors, transistors, etc. The EIC die 108 may include any suitable analog and/or digital circuitry, such as a processor, a memory, an application-specific integrated circuit (ASIC), a field-programmable gate array (FPGA), etc. In some embodiments, the system 100 may be embodied as a router, a switch, a network interface controller, and/or the like. In such embodiments, the EIC die 108 may include network interface controller circuitry to process, parse, route, etc., network packets sent and received by the system 100.

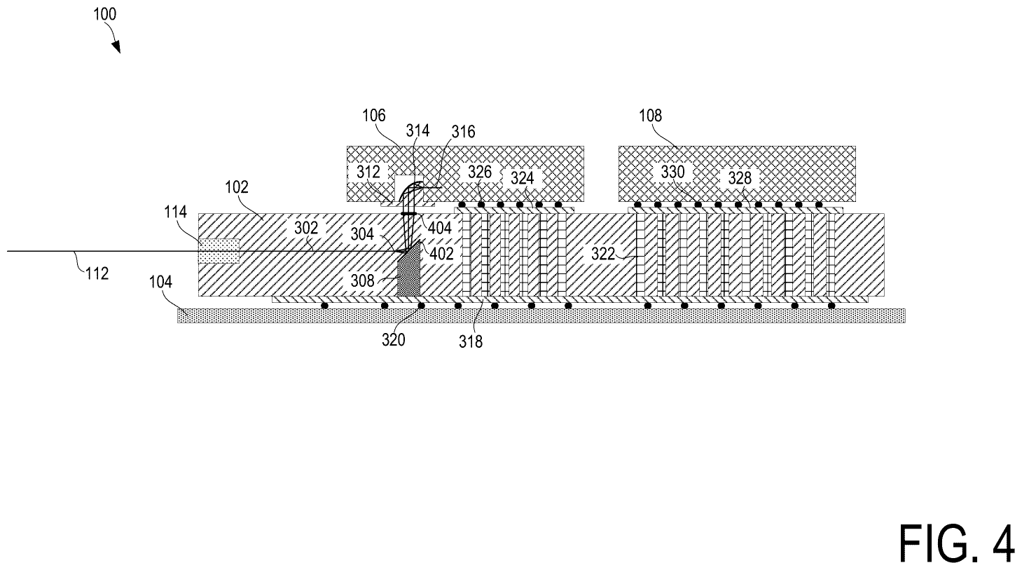

Referring now to FIG. 4, in one embodiment, the system 100 may include a glass substrate 102 with a flat mirror 402 in place of the curved mirror 306. In order to collimate the light coming out of the glass substrate 102, an optical element 404, such as a hologram, diffraction grating, metalens, etc., may collimate the light as it is leaving the glass substrate 102.

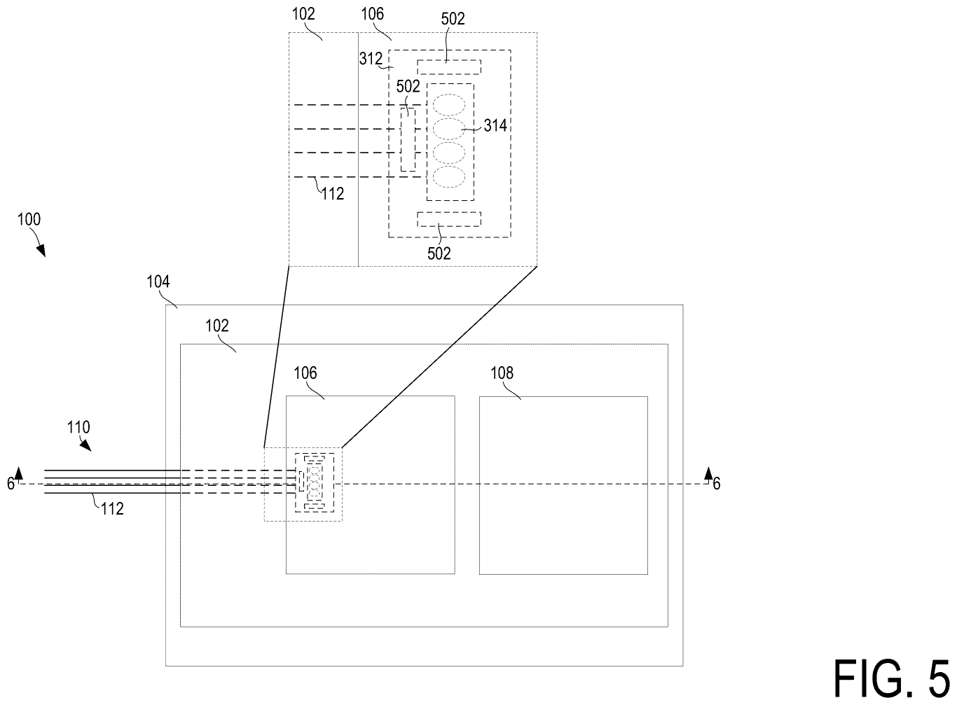

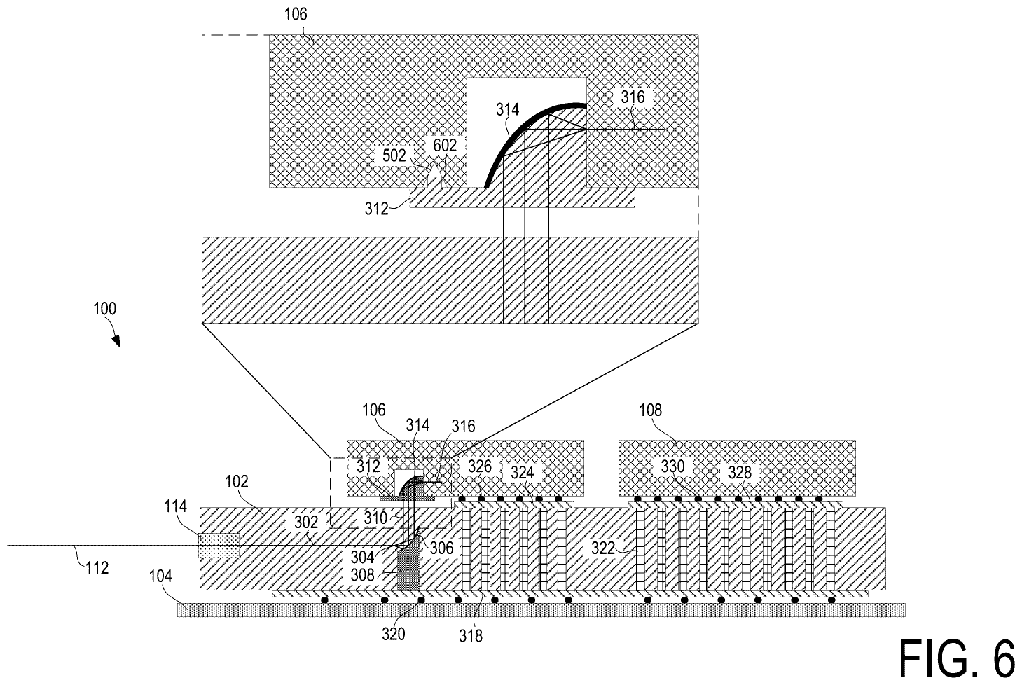

Referring now to FIGS. 5 and 6, in one embodiment, the system 100 may include a PIC die 106 with one or more alignment recesses 502 on the underside of the PIC die 106. FIG. 5 shows a top-down view of such a system 100, and FIG. 6 shows a cross-sectional view of such a system 100. The insert 312 may include alignment protrusions 602 that can be passively aligned to the alignment recesses 502. The alignment of the protrusions 602 to the alignment recesses 502 may ensure that the array of curved mirrors 314 focus the beams 320 into the waveguides 316 of the PIC die 106.

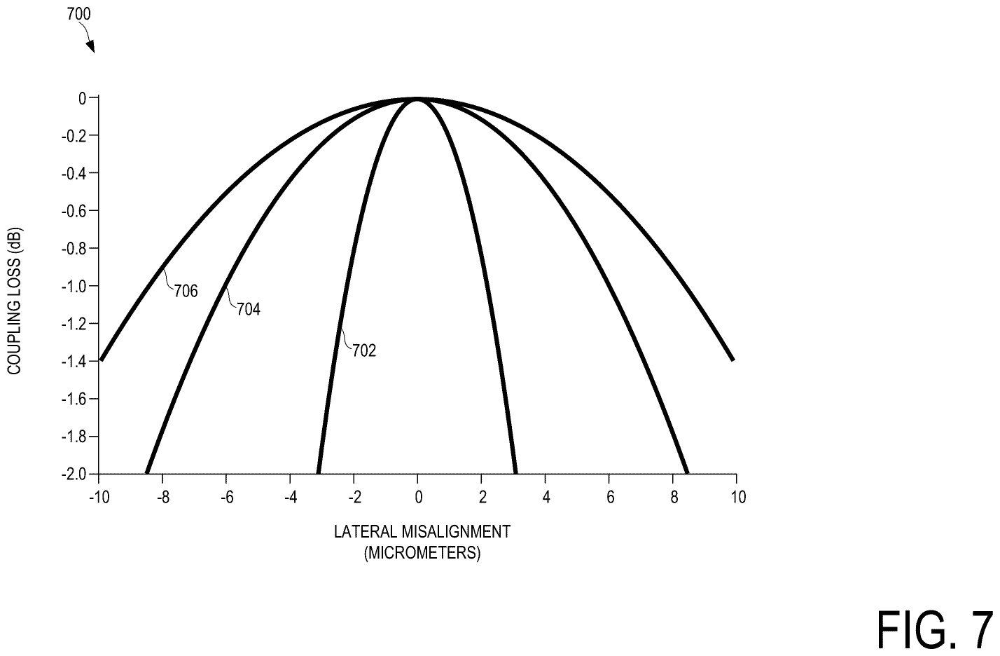

Referring now to FIG. 7, the coupling loss from the beam 310 as a function of lateral misalignment of the PIC die 106 is shown for different beam diameters and for a wavelength of 1,310 nanometers. Curve 702 shows the coupling loss as a function of lateral misalignment for a beam with a mode field diameter of 9.2 micrometers. Curves 704, 706 show the coupling loss as a function of lateral misalignment for a beam with a mode field diameter of 25 micrometers and micrometers, respectively. As the plot 700 shows, the coupling loss decreases as the mode field diameter increases. As discussed above, as the diameter of the collimated beam 310 is significantly larger than the diameter of the beam in the waveguide 302 or waveguide 316, the alignment of the PIC die 106 to the glass substrate 102 is less sensitive than for, e.g., direct coupling between waveguides.

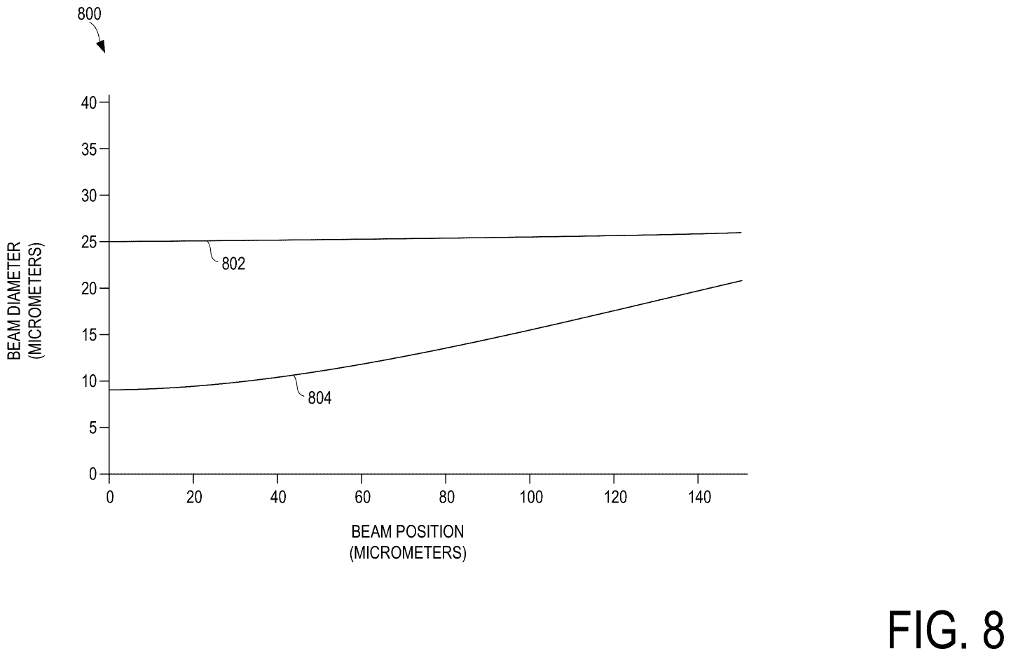

Referring now to FIG. 8, the beam diameter as a function of propagation distance from the minimum beam waist is shown for different beam diameters and for a wavelength of 1,310 nanometers. Curve 802 shows the beam diameter as a function of propagation distance for a beam with a minimum mode field diameter of 25 micrometers, and curve 804 shows the beam diameter as a function of propagation distance for a beam with a minimum mode field diameter of 9.2 micrometers. The plot 800 shows that the beam with the larger minimum mode field diameter diverges much less rapidly in the near field region of, e.g., 0-100 micrometers.

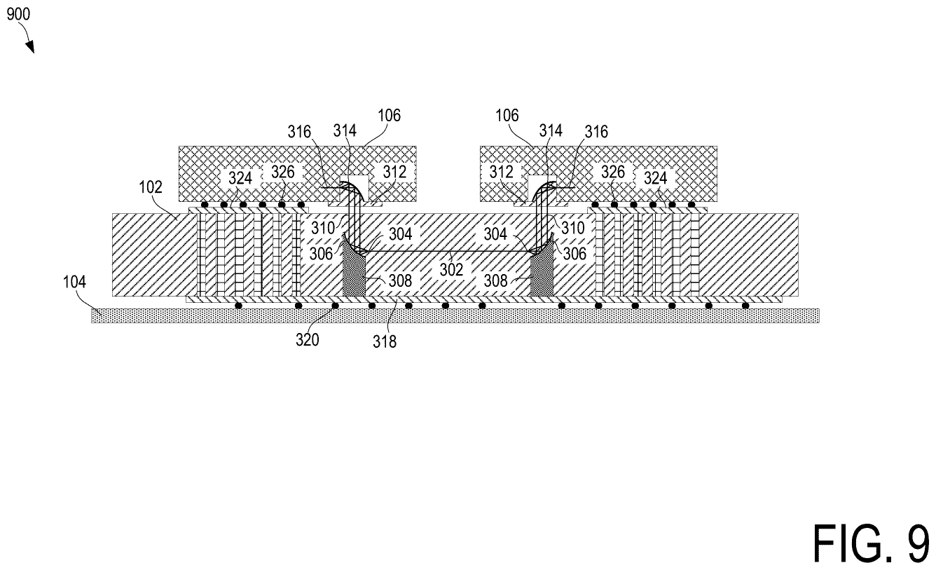

It should be appreciated that the techniques described here may be used for other applications besides coupling light from an optical connector 114 to a PIC die 106. For example, as shown in FIG. 9, in one embodiment, a system 100 may include a glass substrate 102 supporting two PIC dies 106. Light from a waveguide 316 in one PIC die 106 may be collimated into a beam 310 using an insert 312 and coupled into the glass substrate 102. The beam 310 may be focused into a waveguide 302 and routed under the other PIC die 106. The light from the waveguide 302 may be expanded into another beam 310 and coupled into the other PIC die 106. In this manner, the glass substrate 102 may facilitate coupling between two PIC dies 106. In general, the glass substrate 102 may facilitate coupling of light between any suitable components, such as optical connectors, PIC dies, other glass substrates, etc.

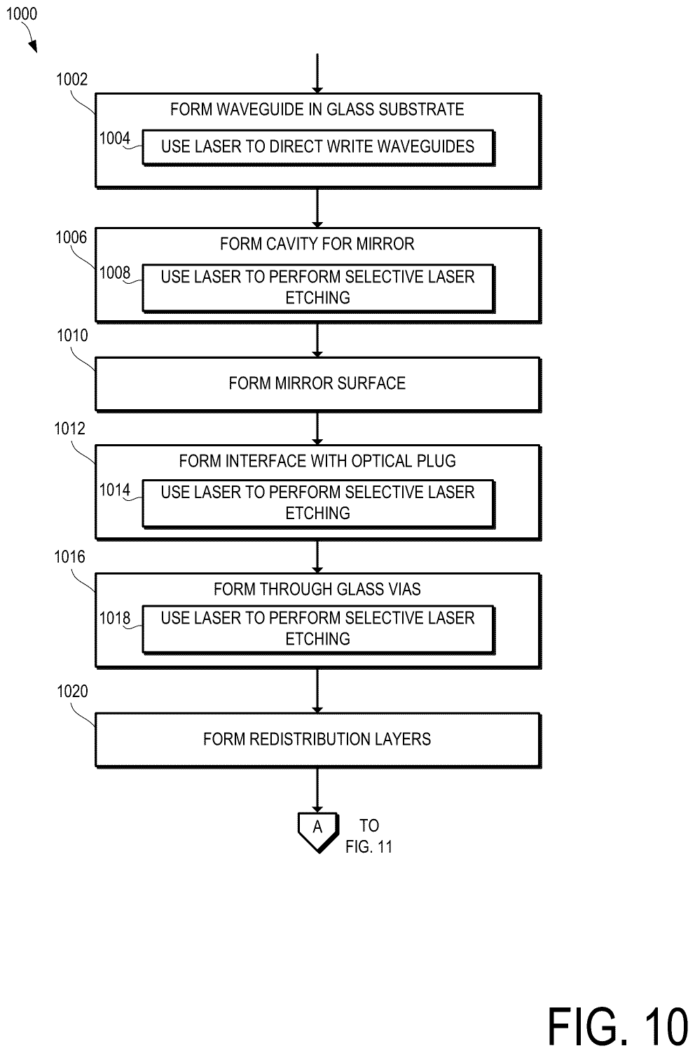

Referring now to FIG. 10, in one embodiment, a flowchart for a method 1000 for creating the system 100 with a glass substrate 102 and a PIC die 106 is shown. The method 1000 may be executed by a technician and/or by one or more automated machines. In some embodiments, one or more machines may be programmed to do some or all of the steps of the method 1000. Such a machine may include, e.g., a memory, a processor, data storage, etc. The memory and/or data storage may store instructions that, when executed by the machine, causes the machine to perform some or all of the steps of the method 1000. The method 1000 may use any suitable set of techniques that are used in semiconductor processing, such as chemical vapor deposition, atomic layer deposition, physical layer deposition, molecular beam epitaxy, layer transfer, photolithography, ion implantation, dry etching, wet etching, selective laser etching, thermal treatments, flip chip, layer transfer, magnetron sputter deposition, pulsed laser deposition, etc. It should be appreciated that the method 1000 is merely one embodiment of a method to create one embodiment of the system 100, and other methods may be used to create any suitable embodiment of the system 100. In some embodiments, steps of the method 1000 may be performed in a different order than that shown in the flowchart.

The method 1000 begins in block 1002, in which one or more waveguides 302 are formed in the glass substrate 102. In the illustrative embodiment, the waveguides 302 are formed using a femtosecond laser to directly write the waveguides 302 in block 1004.

In block 1006, a cavity is formed in the glass substrate 102 for the mirror 306. In the illustrative embodiment, a femtosecond laser is used to perform selective laser etching in block 1008. A femtosecond laser is used to increase the susceptibility of part of the glass substrate 102 to etching, and then an etchant such as hydrofluoric acid etches away the treated portion of the glass. In block 1010, a reflective material such as silver, aluminum, or gold may be applied, or a reflective dielectric stack may be applied. The cavity may then be backfilled with any suitable material, allowing for planarization of the glass substrate 102.

In block 1012, an interface for an optical plug 114 is formed. In block 1014, in the illustrative embodiment, a femtosecond laser is used to perform selective laser etching to create the interface for the optical plug.

In block 1016, through-glass vias 322 are formed in the glass substrate. Selective laser etching may again be used to form the through-glass vias 322 in block 1018. It should be appreciated that, in some embodiments, all of the steps involving selective glass etching may be performed with one etching step. The through-glass vias 322 may then be fully or partially filled with a conductive material, such as copper. In block 1020, redistribution layers 318, 324 may be formed on the top and/or bottom surface of the glass substrate 102.

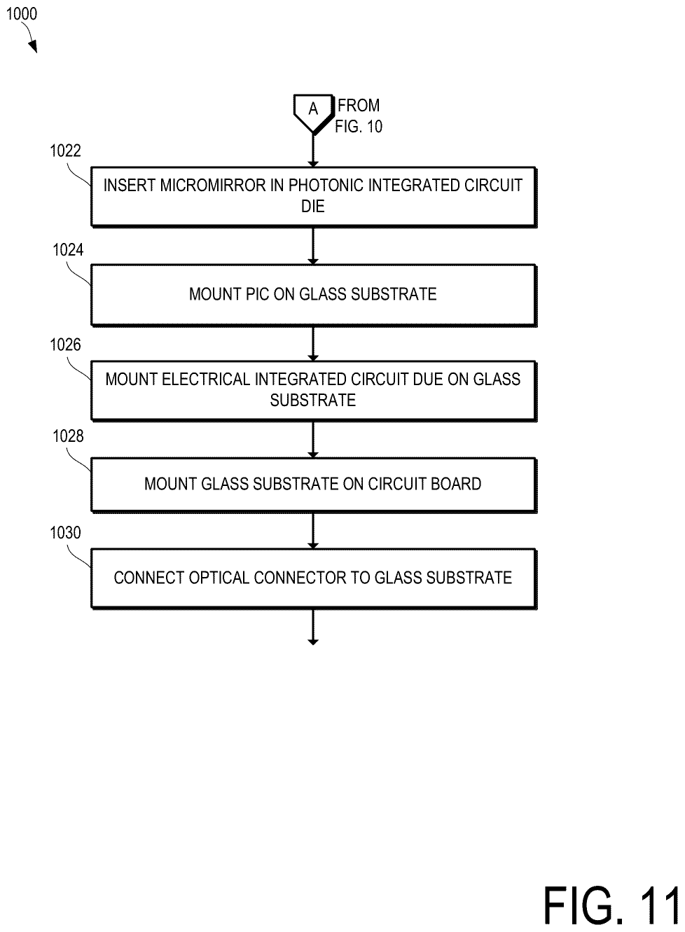

Referring now to FIG. 11, in block 1022, the insert 312 with the micromirrors 314 is inserted into a PIC die 106. The insert 312 may be positioned using a pick and place machine. Alignment recesses 502 in the PIC die 106 may be used to position protrusions 602 of the insert 312. The insert 312 may be fixed in place using, e.g., an adhesive. In some embodiments, an array of inserts 312 may be positioned at the wafer level before the PIC dies 106 are singulated.

In block 1024, the PIC die 106 is mounted on the glass substrate 102. In the illustrative embodiment, the PIC die 106 is mounted by flipping the PIC die over, and solder joints 326 are used to both mechanically and electrically couple the PIC die 106 to the glass substrate 102. In block 1026, an EIC die 108 is mounted on the glass substrate 102 in a similar manner. In some embodiments, the glass substrate 102, the PIC die 106, and/or the EIC die 108 may be tested before assembly, reducing the failure rate.

In block 1028, the glass substrate 102 is mounted on a circuit board 104, such as by using solder joints 320 to mechanically and electrically couple the circuit board 104 to the glass substrate 102.

In block 1030, the optical connector 114 can be connected to the glass substrate 102. It should be appreciated that the optical connector 114 can be connected after other processing steps, such as solder reflow, that may otherwise damage the optical connector 114.

It should be appreciated that the glass substrate 102, without or with the circuit board 104, PIC die 106, and/or the EIC die 108, may be integrated with other components, such as integrated into a multi-chip module alongside other chiplets or otherwise used as a host substrate for larger scale assemblies.

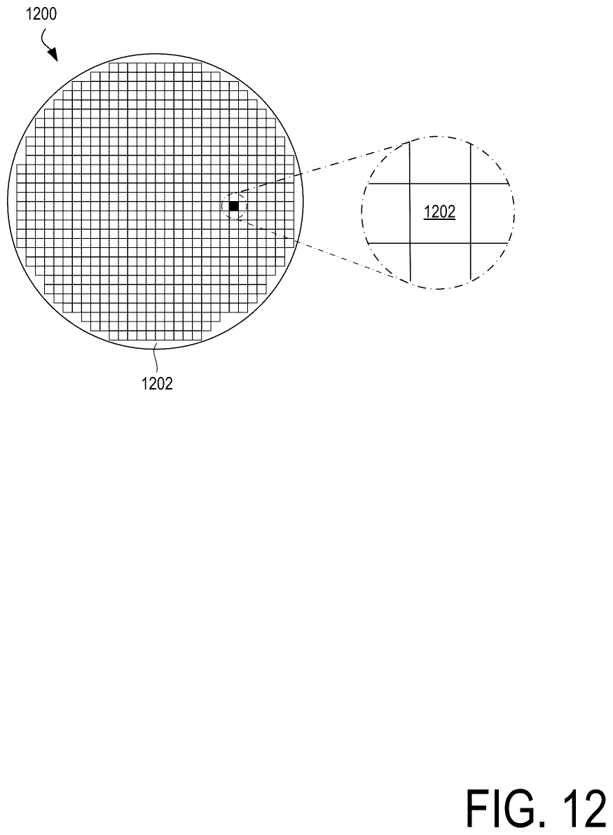

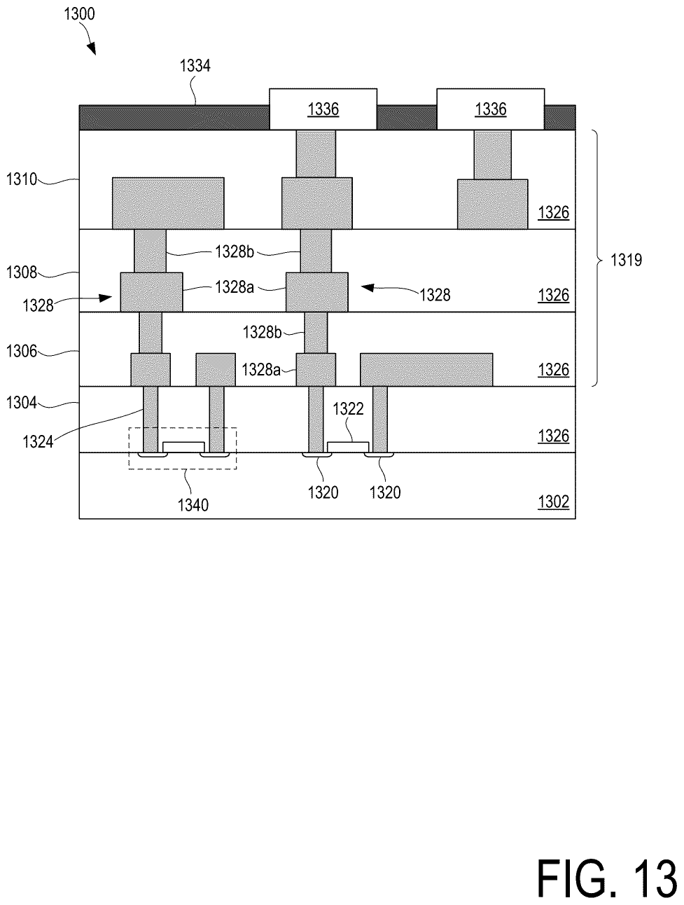

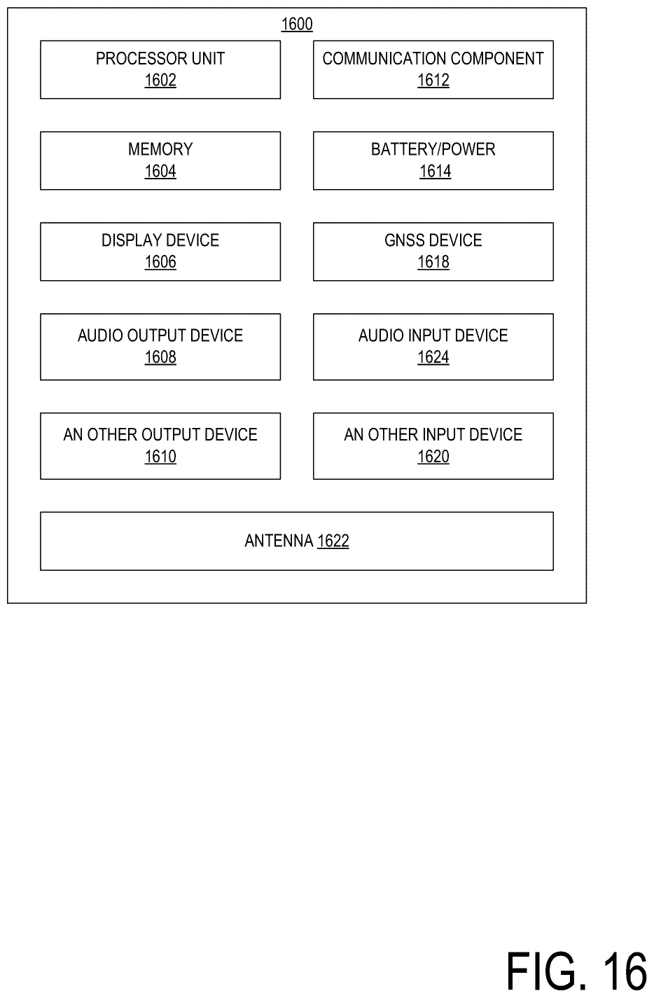

FIG. 12 is a top view of a wafer 1200 and dies 1202 that may be included in any of the systems 100 disclosed herein (e.g., as any suitable ones of the PIC dies 106 or EIC dies 108). The wafer 1200 may be composed of semiconductor material and may include one or more dies 1202 having integrated circuit structures formed on a surface of the wafer 1200. The individual dies 1202 may be a repeating unit of an integrated circuit product that includes any suitable integrated circuit. After the fabrication of the semiconductor product is complete, the wafer 1200 may undergo a singulation process in which the dies 1202 are separated from one another to provide discrete “chips” of the integrated circuit product. The die 1202 may be any of the PIC dies 106 or EIC dies 108 disclosed herein. The die 1202 may include one or more transistors (e.g., some of the transistors 1340 of FIG. 13, discussed below), supporting circuitry to route electrical signals to the transistors, passive components (e.g., signal traces, resistors, capacitors, or inductors), and/or any other integrated circuit components. In some embodiments, the wafer 1200 or the die 1202 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1202. For example, a memory array formed by multiple memory devices may be formed on a same die 1202 as a processor unit (e.g., the processor unit 1602 of FIG. 16) or other logic that is configured to store information in the memory devices or execute instructions stored in the memory array. Various ones of the systems 100 disclosed herein may be manufactured using a die-to-wafer assembly technique in which some PIC dies 106 or EIC dies 108 are attached to a wafer 1200 that include others of the PIC dies 106 or EIC dies 108, and the wafer 1200 is subsequently singulated.

FIG. 13 is a cross-sectional side view of an integrated circuit device 1300 that may be included in any of the system 100 disclosed herein (e.g., in any of the PIC dies 106 or EIC dies 108). One or more of the integrated circuit devices 1300 may be included in one or more dies 1202 (FIG. 12). The integrated circuit device 1300 may be formed on a die substrate 1302 (e.g., the wafer 1200 of FIG. 12) and may be included in a die (e.g., the die 1202 of FIG. 12). The die substrate 1302 may be a semiconductor substrate composed of semiconductor material systems including, for example, n-type or p-type materials systems (or a combination of both). The die substrate 1302 may include, for example, a crystalline substrate formed using a bulk silicon or a silicon-on-insulator (SOI) substructure. In some embodiments, the die substrate 1302 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 1302. Although a few examples of materials from which the die substrate 1302 may be formed are described here, any material that may serve as a foundation for an integrated circuit device 1300 may be used. The die substrate 1302 may be part of a singulated die (e.g., the dies 1202 of FIG. 12) or a wafer (e.g., the wafer 1200 of FIG. 12).

The integrated circuit device 1300 may include one or more device layers 1304 disposed on the die substrate 1302. The device layer 1304 may include features of one or more transistors 1340 (e.g., metal oxide semiconductor field-effect transistors (MOSFETs)) formed on the die substrate 1302. The transistors 1340 may include, for example, one or more source and/or drain (S/D) regions 1320, a gate 1322 to control current flow between the S/D regions 1320, and one or more S/D contacts 1324 to route electrical signals to/from the S/D regions 1320. The transistors 1340 may include additional features not depicted for the sake of clarity, such as device isolation regions, gate contacts, and the like. The transistors 1340 are not limited to the type and configuration depicted in FIG. 13 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

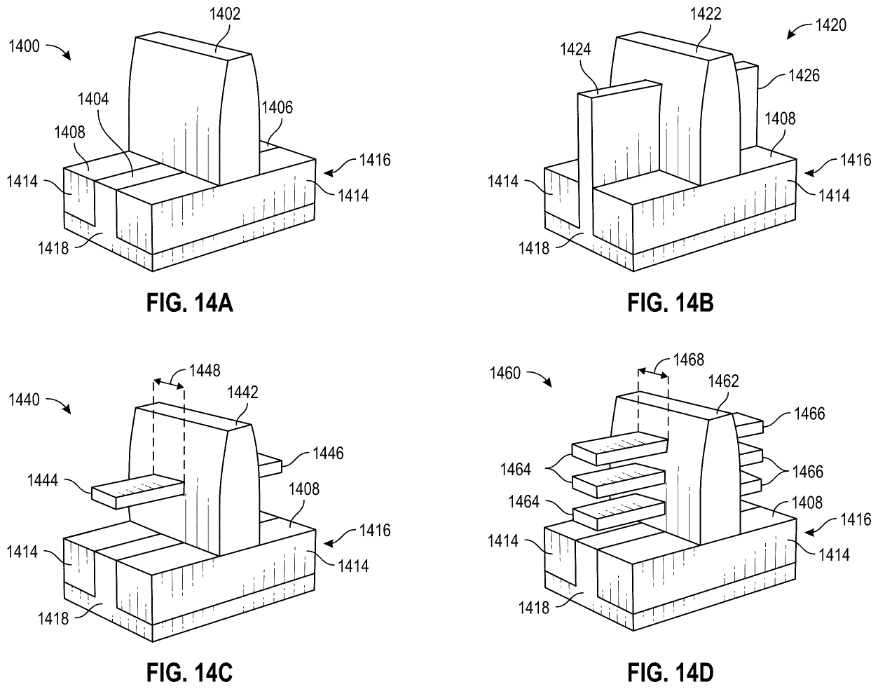

FIGS. 14A-14D are simplified perspective views of example planar, FinFET, gate-all-around, and stacked gate-all-around transistors. The transistors illustrated in FIGS. 14A-14D are formed on a substrate 1416 having a surface 1408. Isolation regions 1414 separate the source and drain regions of the transistors from other transistors and from a bulk region 1418 of the substrate 1416.

FIG. 14A is a perspective view of an example planar transistor 1400 comprising a gate 1402 that controls current flow between a source region 1404 and a drain region 1406. The transistor 1400 is planar in that the source region 1404 and the drain region 1406 are planar with respect to the substrate surface 1408.

FIG. 14B is a perspective view of an example FinFET transistor 1420 comprising a gate 1422 that controls current flow between a source region 1424 and a drain region 1426. The transistor 1420 is non-planar in that the source region 1424 and the drain region 1426 comprise “fins” that extend upwards from the substrate surface 1428. As the gate 1422 encompasses three sides of the semiconductor fin that extends from the source region 1424 to the drain region 1426, the transistor 1420 can be considered a tri-gate transistor. FIG. 14B illustrates one S/D fin extending through the gate 1422, but multiple S/D fins can extend through the gate of a FinFET transistor.

FIG. 14C is a perspective view of a gate-all-around (GAA) transistor 1440 comprising a gate 1442 that controls current flow between a source region 1444 and a drain region 1446. The transistor 1440 is non-planar in that the source region 1444 and the drain region 1446 are elevated from the substrate surface 1428.

FIG. 14D is a perspective view of a GAA transistor 1460 comprising a gate 1462 that controls current flow between multiple elevated source regions 1464 and multiple elevated drain regions 1466. The transistor 1460 is a stacked GAA transistor as the gate controls the flow of current between multiple elevated S/D regions stacked on top of each other. The transistors 1440 and 1460 are considered gate-all-around transistors as the gates encompass all sides of the semiconductor portions that extends from the source regions to the drain regions. The transistors 1440 and 1460 can alternatively be referred to as nanowire, nanosheet, or nanoribbon transistors depending on the width (e.g., widths 1448 and 1468 of transistors 1440 and 1460, respectively) of the semiconductor portions extending through the gate.

Returning to FIG. 13, a transistor 1340 may include a gate 1322 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 1340 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1340 along the source-channel-drain direction, the gate electrode may consist of a U-shaped structure that includes a bottom portion substantially parallel to the surface of the die substrate 1302 and two sidewall portions that are substantially perpendicular to the top surface of the die substrate 1302. In other embodiments, at least one of the metal layers that form the gate electrode may simply be a planar layer that is substantially parallel to the top surface of the die substrate 1302 and does not include sidewall portions substantially perpendicular to the top surface of the die substrate 1302. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1320 may be formed within the die substrate 1302 adjacent to the gate 1322 of individual transistors 1340. The S/D regions 1320 may be formed using an implantation/diffusion process or an etching/deposition process, for example. In the former process, dopants such as boron, aluminum, antimony, phosphorous, or arsenic may be ion-implanted into the die substrate 1302 to form the S/D regions 1320. An annealing process that activates the dopants and causes them to diffuse farther into the die substrate 1302 may follow the ion-implantation process. In the latter process, the die substrate 1302 may first be etched to form recesses at the locations of the S/D regions 1320. An epitaxial deposition process may then be carried out to fill the recesses with material that is used to fabricate the S/D regions 1320. In some implementations, the S/D regions 1320 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1320 may be formed using one or more alternate semiconductor materials such as germanium or a group III-V material or alloy. In further embodiments, one or more layers of metal and/or metal alloys may be used to form the S/D regions 1320.

Electrical signals, such as power and/or input/output (I/O) signals, may be routed to and/or from the devices (e.g., transistors 1340) of the device layer 1304 through one or more interconnect layers disposed on the device layer 1304 (illustrated in FIG. 13 as interconnect layers 1306-1310). For example, electrically conductive features of the device layer 1304 (e.g., the gate 1322 and the S/D contacts 1324) may be electrically coupled with the interconnect structures 1328 of the interconnect layers 1306-1310. The one or more interconnect layers 1306-1310 may form a metallization stack (also referred to as an “ILD stack”) 1319 of the integrated circuit device 1300.

The interconnect structures 1328 may be arranged within the interconnect layers 1306-1310 to route electrical signals according to a wide variety of designs; in particular, the arrangement is not limited to the particular configuration of interconnect structures 1328 depicted in FIG. 13. Although a particular number of interconnect layers 1306-1310 is depicted in FIG. 13, embodiments of the present disclosure include integrated circuit devices having more or fewer interconnect layers than depicted.

In some embodiments, the interconnect structures 1328 may include lines 1328a and/or vias 1328b filled with an electrically conductive material such as a metal. The lines 1328a may be arranged to route electrical signals in a direction of a plane that is substantially parallel with a surface of the die substrate 1302 upon which the device layer 1304 is formed. For example, the lines 1328a may route electrical signals in a direction in and out of the page and/or in a direction across the page. The vias 1328b may be arranged to route electrical signals in a direction of a plane that is substantially perpendicular to the surface of the die substrate 1302 upon which the device layer 1304 is formed. In some embodiments, the vias 1328b may electrically couple lines 1328a of different interconnect layers 1306-1310 together.

The interconnect layers 1306-1310 may include a dielectric material 1326 disposed between the interconnect structures 1328, as shown in FIG. 13. In some embodiments, dielectric material 1326 disposed between the interconnect structures 1328 in different ones of the interconnect layers 1306-1310 may have different compositions; in other embodiments, the composition of the dielectric material 1326 between different interconnect layers 1306-1310 may be the same. The device layer 1304 may include a dielectric material 1326 disposed between the transistors 1340 and a bottom layer of the metallization stack as well. The dielectric material 1326 included in the device layer 1304 may have a different composition than the dielectric material 1326 included in the interconnect layers 1306-1310; in other embodiments, the composition of the dielectric material 1326 in the device layer 1304 may be the same as a dielectric material 1326 included in any one of the interconnect layers 1306-1310.

A first interconnect layer 1306 (referred to as Metal 1 or “M1”) may be formed directly on the device layer 1304. In some embodiments, the first interconnect layer 1306 may include lines 1328a and/or vias 1328b, as shown. The lines 1328a of the first interconnect layer 1306 may be coupled with contacts (e.g., the S/D contacts 1324) of the device layer 1304. The vias 1328b of the first interconnect layer 1306 may be coupled with the lines 1328a of a second interconnect layer 1308.

The second interconnect layer 1308 (referred to as Metal 2 or “M2”) may be formed directly on the first interconnect layer 1306. In some embodiments, the second interconnect layer 1308 may include via 1328b to couple the lines 1328 of the second interconnect layer 1308 with the lines 1328a of a third interconnect layer 1310. Although the lines 1328a and the vias 1328b are structurally delineated with a line within individual interconnect layers for the sake of clarity, the lines 1328a and the vias 1328b may be structurally and/or materially contiguous (e.g., simultaneously filled during a dual-damascene process) in some embodiments.

The third interconnect layer 1310 (referred to as Metal 3 or “M3”) (and additional interconnect layers, as desired) may be formed in succession on the second interconnect layer 1308 according to similar techniques and configurations described in connection with the second interconnect layer 1308 or the first interconnect layer 1306. In some embodiments, the interconnect layers that are “higher up” in the metallization stack 1319 in the integrated circuit device 1300 (i.e., farther away from the device layer 1304) may be thicker that the interconnect layers that are lower in the metallization stack 1319, with lines 1328a and vias 1328b in the higher interconnect layers being thicker than those in the lower interconnect layers.

The integrated circuit device 1300 may include a solder resist material 1334 (e.g., polyimide or similar material) and one or more conductive contacts 1336 formed on the interconnect layers 1306-1310. In FIG. 13, the conductive contacts 1336 are illustrated as taking the form of bond pads. The conductive contacts 1336 may be electrically coupled with the interconnect structures 1328 and configured to route the electrical signals of the transistor(s) 1340 to external devices. For example, solder bonds may be formed on the one or more conductive contacts 1336 to mechanically and/or electrically couple an integrated circuit die including the integrated circuit device 1300 with another component (e.g., a printed circuit board). The integrated circuit device 1300 may include additional or alternate structures to route the electrical signals from the interconnect layers 1306-1310; for example, the conductive contacts 1336 may include other analogous features (e.g., posts) that route the electrical signals to external components.

In some embodiments in which the integrated circuit device 1300 is a double-sided die, the integrated circuit device 1300 may include another metallization stack (not shown) on the opposite side of the device layer(s) 1304. This metallization stack may include multiple interconnect layers as discussed above with reference to the interconnect layers 1306-1310, to provide conductive pathways (e.g., including conductive lines and vias) between the device layer(s) 1304 and additional conductive contacts (not shown) on the opposite side of the integrated circuit device 1300 from the conductive contacts 1336.

In other embodiments in which the integrated circuit device 1300 is a double-sided die, the integrated circuit device 1300 may include one or more through silicon vias (TSVs) through the die substrate 1302; these TSVs may make contact with the device layer(s) 1304, and may provide conductive pathways between the device layer(s) 1304 and additional conductive contacts (not shown) on the opposite side of the integrated circuit device 1300 from the conductive contacts 1336. In some embodiments, TSVs extending through the substrate can be used for routing power and ground signals from conductive contacts on the opposite side of the integrated circuit device 1300 from the conductive contacts 1336 to the transistors 1340 and any other components integrated into the die 1300, and the metallization stack 1319 can be used to route I/O signals from the conductive contacts 1336 to transistors 1340 and any other components integrated into the die 1300.

Multiple integrated circuit devices 1300 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

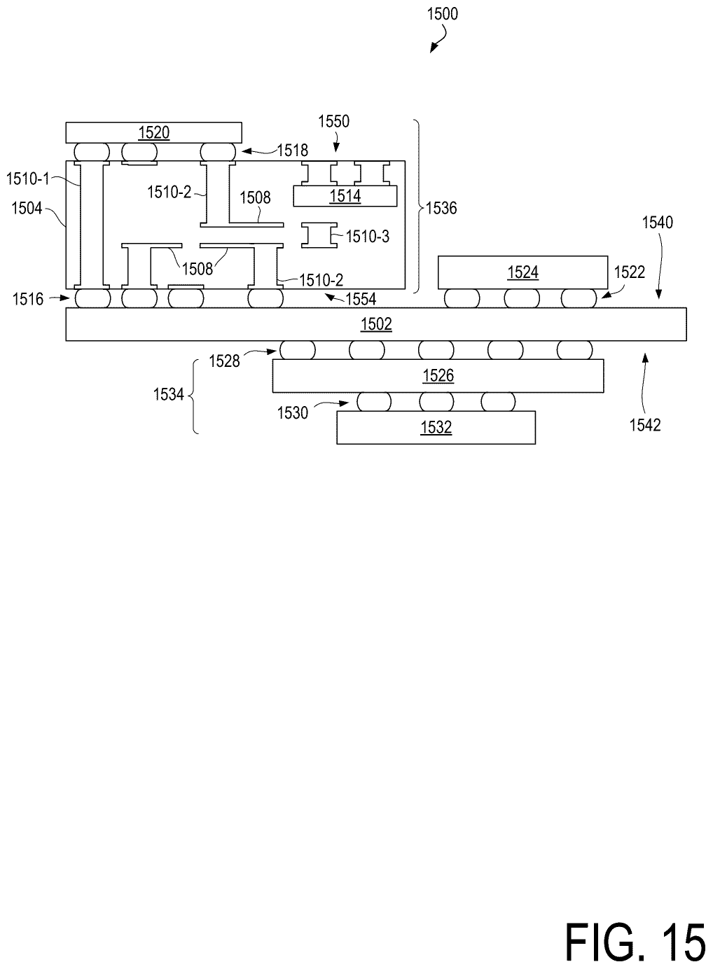

FIG. 15 is a cross-sectional side view of an integrated circuit device assembly 1500 that may be included in any of the systems 100 disclosed herein. In some embodiments, the integrated circuit device assembly 1500 may be a PIC die 106 or EIC die 108. The integrated circuit device assembly 1500 includes a number of components disposed on a circuit board 1502 (which may be a motherboard, system board, mainboard, etc.). The integrated circuit device assembly 1500 includes components disposed on a first face 1540 of the circuit board 1502 and an opposing second face 1542 of the circuit board 1502; generally, components may be disposed on one or both faces 1540 and 1542. Any of the integrated circuit components discussed below with reference to the integrated circuit device assembly 1500 may take the form of any suitable ones of the embodiments of the PIC dies 106 or EIC dies 108 disclosed herein.

In some embodiments, the circuit board 1502 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1502. In other embodiments, the circuit board 1502 may be a non-PCB substrate. In some embodiments the circuit board 1502 may be, for example, the circuit board 104. The integrated circuit device assembly 1500 illustrated in FIG. 15 includes a package-on-interposer structure 1536 coupled to the first face 1540 of the circuit board 1502 by coupling components 1516. The coupling components 1516 may electrically and mechanically couple the package-on-interposer structure 1536 to the circuit board 1502, and may include solder balls (as shown in FIG. 15), pins (e.g., as part of a pin grid array (PGA), contacts (e.g., as part of a land grid array (LGA)), male and female portions of a socket, an adhesive, an underfill material, and/or any other suitable electrical and/or mechanical coupling structure. The coupling components 1516 may serve as the coupling components illustrated or described for any of the substrate assembly or substrate assembly components described herein, as appropriate.

The package-on-interposer structure 1536 may include an integrated circuit component 1520 coupled to an interposer 1504 by coupling components 1518. The coupling components 1518 may take any suitable form for the application, such as the forms discussed above with reference to the coupling components 1516. Although a single integrated circuit component 1520 is shown in FIG. 15, multiple integrated circuit components may be coupled to the interposer 1504; indeed, additional interposers may be coupled to the interposer 1504. The interposer 1504 may provide an intervening substrate used to bridge the circuit board 1502 and the integrated circuit component 1520.

The integrated circuit component 1520 may be a packaged or unpacked integrated circuit product that includes one or more integrated circuit dies (e.g., the die 1202 of FIG. 12, the integrated circuit device 1300 of FIG. 13) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 1520, a single monolithic integrated circuit die comprises solder bumps attached to contacts on the die. The solder bumps allow the die to be directly attached to the interposer 1504. The integrated circuit component 1520 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 1520 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 1520 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 1520 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 1504 may spread connections to a wider pitch or reroute a connection to a different connection. For example, the interposer 1504 may couple the integrated circuit component 1520 to a set of ball grid array (BGA) conductive contacts of the coupling components 1516 for coupling to the circuit board 1502. In the embodiment illustrated in FIG. the integrated circuit component 1520 and the circuit board 1502 are attached to opposing sides of the interposer 1504; in other embodiments, the integrated circuit component 1520 and the circuit board 1502 may be attached to a same side of the interposer 1504. In some embodiments, three or more components may be interconnected by way of the interposer 1504.

In some embodiments, the interposer 1504 may be formed as a PCB, including multiple metal layers separated from one another by layers of dielectric material and interconnected by electrically conductive vias. In some embodiments, the interposer 1504 may be formed of an epoxy resin, a fiberglass-reinforced epoxy resin, an epoxy resin with inorganic fillers, a ceramic material, or a polymer material such as polyimide. In some embodiments, the interposer 1504 may be formed of alternate rigid or flexible materials that may include the same materials described above for use in a semiconductor substrate, such as silicon, germanium, and other group III-V and group IV materials. The interposer 1504 may include metal interconnects 1508 and vias 1510, including but not limited to through hole vias 1510-1 (that extend from a first face 1550 of the interposer 1504 to a second face 1554 of the interposer 1504), blind vias 1510-2 (that extend from the first or second faces 1550 or 1554 of the interposer 1504 to an internal metal layer), and buried vias 1510-3 (that connect internal metal layers).

In some embodiments, the interposer 1504 can comprise a silicon interposer. Through silicon vias (TSV) extending through the silicon interposer can connect connections on a first face of a silicon interposer to an opposing second face of the silicon interposer. In some embodiments, an interposer 1504 comprising a silicon interposer can further comprise one or more routing layers to route connections on a first face of the interposer 1504 to an opposing second face of the interposer 1504.

The interposer 1504 may further include embedded devices 1514, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1504. The package-on-interposer structure 1536 may take the form of any of the package-on-interposer structures known in the art. In embodiments where the interposer is a non-printed circuit board

The integrated circuit device assembly 1500 may include an integrated circuit component 1524 coupled to the first face 1540 of the circuit board 1502 by coupling components 1522. The coupling components 1522 may take the form of any of the embodiments discussed above with reference to the coupling components 1516, and the integrated circuit component 1524 may take the form of any of the embodiments discussed above with reference to the integrated circuit component 1520.

The integrated circuit device assembly 1500 illustrated in FIG. 15 includes a package-on-package structure 1534 coupled to the second face 1542 of the circuit board 1502 by coupling components 1528. The package-on-package structure 1534 may include an integrated circuit component 1526 and an integrated circuit component 1532 coupled together by coupling components 1530 such that the integrated circuit component 1526 is disposed between the circuit board 1502 and the integrated circuit component 1532. The coupling components 1528 and 1530 may take the form of any of the embodiments of the coupling components 1516 discussed above, and the integrated circuit components 1526 and 1532 may take the form of any of the embodiments of the integrated circuit component 1520 discussed above. The package-on-package structure 1534 may be configured in accordance with any of the package-on-package structures known in the art.

FIG. 16 is a block diagram of an example electrical device 1600 that may include some or all of the systems 100 disclosed herein. For example, any suitable ones of the components of the electrical device 1600 may include one or more of the integrated circuit device assemblies 1500, integrated circuit components 1520, integrated circuit devices 1300, or integrated circuit dies 1202 disclosed herein, and may be arranged in any of the systems 100 disclosed herein. A number of components are illustrated in FIG. 16 as included in the electrical device 1600, but any one or more of these components may be omitted or duplicated, as suitable for the application. In some embodiments, some or all of the components included in the electrical device 1600 may be attached to one or more motherboards mainboards, or system boards. In some embodiments, one or more of these components are fabricated onto a single system-on-a-chip (SoC) die.

Additionally, in various embodiments, the electrical device 1600 may not include one or more of the components illustrated in FIG. 16, but the electrical device 1600 may include interface circuitry for coupling to the one or more components. For example, the electrical device 1600 may not include a display device 1606, but may include display device interface circuitry (e.g., a connector and driver circuitry) to which a display device 1606 may be coupled. In another set of examples, the electrical device 1600 may not include an audio input device 1624 or an audio output device 1608, but may include audio input or output device interface circuitry (e.g., connectors and supporting circuitry) to which an audio input device 1624 or audio output device 1608 may be coupled.

The electrical device 1600 may include one or more processor units 1602 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1602 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1600 may include a memory 1604, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1604 may include memory that is located on the same integrated circuit die as the processor unit 1602. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 1600 can comprise one or more processor units 1602 that are heterogeneous or asymmetric to another processor unit 1602 in the electrical device 1600. There can be a variety of differences between the processing units 1602 in a system in terms of a spectrum of metrics of merit including architectural, microarchitectural, thermal, power consumption characteristics, and the like. These differences can effectively manifest themselves as asymmetry and heterogeneity among the processor units 1602 in the electrical device 1600.

In some embodiments, the electrical device 1600 may include a communication component 1612 (e.g., one or more communication components). For example, the communication component 1612 can manage wireless communications for the transfer of data to and from the electrical device 1600. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1612 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1612 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1612 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1612 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1612 may operate in accordance with other wireless protocols in other embodiments. The electrical device 1600 may include an antenna 1622 to facilitate wireless communications and/or to receive other wireless communications (such as AM or FM radio transmissions).

In some embodiments, the communication component 1612 may manage wired communications, such as electrical, optical, or any other suitable communication protocols (e.g., IEEE 802.3 Ethernet standards). As noted above, the communication component 1612 may include multiple communication components. For instance, a first communication component 1612 may be dedicated to shorter-range wireless communications such as Wi-Fi or Bluetooth, and a second communication component 1612 may be dedicated to longer-range wireless communications such as global positioning system (GPS), EDGE, GPRS, CDMA, WiMAX, LTE, EV-DO, or others. In some embodiments, a first communication component 1612 may be dedicated to wireless communications, and a second communication component 1612 may be dedicated to wired communications.

The electrical device 1600 may include battery/power circuitry 1614. The battery/power circuitry 1614 may include one or more energy storage devices (e.g., batteries or capacitors) and/or circuitry for coupling components of the electrical device 1600 to an energy source separate from the electrical device 1600 (e.g., AC line power).

The electrical device 1600 may include a display device 1606 (or corresponding interface circuitry, as discussed above). The display device 1606 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1600 may include an audio output device 1608 (or corresponding interface circuitry, as discussed above). The audio output device 1608 may include any embedded or wired or wirelessly connected external device that generates an audible indicator, such speakers, headsets, or earbuds.

The electrical device 1600 may include an audio input device 1624 (or corresponding interface circuitry, as discussed above). The audio input device 1624 may include any embedded or wired or wirelessly connected device that generates a signal representative of a sound, such as microphones, microphone arrays, or digital instruments (e.g., instruments having a musical instrument digital interface (MIDI) output). The electrical device 1600 may include a Global Navigation Satellite System (GNSS) device 1618 (or corresponding interface circuitry, as discussed above), such as a Global Positioning System (GPS) device. The GNSS device 1618 may be in communication with a satellite-based system and may determine a geolocation of the electrical device 1600 based on information received from one or more GNSS satellites, as known in the art.

The electrical device 1600 may include an other output device 1610 (or corresponding interface circuitry, as discussed above). Examples of the other output device 1610 may include an audio codec, a video codec, a printer, a wired or wireless transmitter for providing information to other devices, or an additional storage device.

The electrical device 1600 may include an other input device 1620 (or corresponding interface circuitry, as discussed above). Examples of the other input device 1620 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1600 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1600 may be any other electronic device that processes data. In some embodiments, the electrical device 1600 may comprise multiple discrete physical components. Given the range of devices that the electrical device 1600 can be manifested as in various embodiments, in some embodiments, the electrical device 1600 can be referred to as a computing device or a computing system.

### EXAMPLES

Illustrative examples of the technologies disclosed herein are provided below. An embodiment of the technologies may include any one or more, and any combination of, the examples described below.

Example 1 includes an apparatus comprising a glass substrate comprising one or more waveguides; and one or more curved mirrors defined in the glass substrate, wherein individual waveguides of the one or more waveguides are to direct light individual curved mirrors of the one or more curved mirrors, wherein individual curved mirrors of the one or more curved mirrors are to collimate light from individual waveguides of the one or more waveguides.

Example 2 includes the subject matter of Example 1, and further including a photonic integrated circuit (PIC) die mounted on a top surface of the glass substrate, wherein individual curved mirrors of the one or more curved mirrors are to direct light from individual waveguides of the one or more waveguides out of the top surface towards the PIC die.

Example 3 includes the subject matter of any of Examples 1 and 2, and wherein the PIC die comprises one or more waveguides, the apparatus further comprising an optical insert mounted on the PIC die, wherein the optical insert comprises one or more curved mirrors, wherein individual curved mirrors of the one or more curved mirrors of the optical insert are to focus light collimated by individual curved mirrors of the one or more curved mirrors of the glass substrate to individual waveguides of the one or more waveguides of the PIC die.

Example 4 includes the subject matter of any of Examples 1-3, and further including a plurality of solder bumps that join the glass substrate and the PIC die, wherein individual solder bumps of the plurality of solder bumps electrically couple the glass substrate to the PIC die.

Example 5 includes the subject matter of any of Examples 1-4, and wherein the glass substrate comprises a plurality of through-glass vias, wherein individual through-glass vias of the plurality of through-glass vias are electrically coupled to individual solder bumps of the plurality of solder bumps.

Example 6 includes the subject matter of any of Examples 1-5, and further including an electronic integrated circuit (EIC) die mounted on the top surface of the glass substrate, further comprising an additional plurality of solder bumps that join the glass substrate and the EIC die, wherein individual solder bumps of the additional plurality of solder bumps electrically couple the glass substrate to the EIC die.

Example 7 includes the subject matter of any of Examples 1-6, and wherein the glass substrate comprises a plurality of through-glass vias, wherein individual through-glass vias of the plurality of through-glass vias are electrically coupled to individual solder bumps of the additional plurality of solder bumps.

Example 8 includes the subject matter of any of Examples 1-7, and further including a second PIC die mounted on the top surface of the glass substrate, the glass substrate further comprising a second curved mirror defined in the glass substrate and a third curved mirror defined in the glass substrate, wherein the second curved mirror is to focus collimated light from the second PIC die to a waveguide of the one or more waveguides of the glass substrate, wherein the third curved mirror is to collimate light from the waveguide into a beam and direct the beam out of the top surface towards the PIC die.

Example 9 includes the subject matter of any of Examples 1-8, and further including an optical connector, wherein an interface for the optical connector is defined in the glass substrate, wherein the optical connector is mated with the glass substrate.

Example 10 includes the subject matter of any of Examples 1-9, and further including a redistribution layer on a top surface of the glass substrate.

Example 11 includes the subject matter of any of Examples 1-10, and further including a circuit board, wherein the glass substrate is mounted on the circuit board.

Example 12 includes the subject matter of any of Examples 1-11, and wherein individual curved mirrors of the one or more curved mirrors defined in the glass substrate comprise a reflective surface.

Example 13 includes the subject matter of any of Examples 1-12, and wherein the reflective surface of individual curved mirrors of the one or more curved mirrors comprises aluminum or silver.

Example 14 includes the subject matter of any of Examples 1-13, and wherein the reflective surface of individual curved mirrors of the one or more curved mirrors comprises a dielectric stack.

Example 15 includes the subject matter of any of Examples 1-14, and wherein individual curved mirrors of the one or more curved mirrors defined in the glass substrate are reflective due to total internal reflection.

Example 16 includes an apparatus comprising a glass substrate comprising means for interfacing with an optical connector that comprises one or more optical fibers; and means for collimating light from the one or more optical fibers.

Example 17 includes the subject matter of Example 16, and wherein the means for collimating light from the one or more optical fibers comprises one or more curved mirrors defined in the glass substrate.

Example 18 includes the subject matter of any of Examples 16 and 17, and wherein individual curved mirrors of the one or more curved mirrors defined in the glass substrate comprise a reflective surface.

Example 19 includes the subject matter of any of Examples 16-18, and wherein the reflective surface of individual curved mirrors of the one or more curved mirrors comprises aluminum or silver.

Example 20 includes the subject matter of any of Examples 16-19, and wherein the reflective surface of individual curved mirrors of the one or more curved mirrors comprises a dielectric stack.

Example 21 includes the subject matter of any of Examples 16-20, and wherein individual curved mirrors of the one or more curved mirrors defined in the glass substrate are reflective due to total internal reflection.

Example 22 includes the subject matter of any of Examples 16-21, and further including a photonic integrated circuit (PIC) die mounted on a top surface of the glass substrate, wherein the means for collimating light from the one or more optical fibers are to direct collimated light out of the top surface towards the PIC die.

Example 23 includes the subject matter of any of Examples 16-22, and wherein the PIC die comprises one or more waveguides, the apparatus further comprising an optical insert mounted on the PIC die, wherein the optical insert comprises one or more curved mirrors, wherein individual curved mirrors of the one or more curved mirrors of the optical insert are to focus light collimated by the means for collimating light from the one or more optical fibers to individual waveguides of the one or more waveguides of the PIC die.

Example 24 includes the subject matter of any of Examples 16-23, and further including a plurality of solder bumps that join the glass substrate and the PIC die, wherein individual solder bumps of the plurality of solder bumps electrically couple the glass substrate to the PIC die.

Example 25 includes the subject matter of any of Examples 16-24, and wherein the glass substrate comprises a plurality of through-glass vias, wherein individual through-glass vias of the plurality of through-glass vias are electrically coupled to individual solder bumps of the plurality of solder bumps.

Example 26 includes the subject matter of any of Examples 16-25, and further including an electronic integrated circuit (EIC) die mounted on the top surface of the glass substrate, further comprising an additional plurality of solder bumps that join the glass substrate and the EIC die, wherein individual solder bumps of the additional plurality of solder bumps electrically couple the glass substrate to the EIC die.

Example 27 includes the subject matter of any of Examples 16-26, and wherein the glass substrate comprises a plurality of through-glass vias, wherein individual through-glass vias of the plurality of through-glass vias are electrically coupled to individual solder bumps of the additional plurality of solder bumps.

Example 28 includes the subject matter of any of Examples 16-27, and further including a second PIC die mounted on the top surface of the glass substrate, the glass substrate further comprising means for receiving collimated light from the second PIC die and directing corresponding collimated light to the PIC die.

Example 29 includes the subject matter of any of Examples 16-28, and further including the optical connector.

Example 30 includes a method comprising direct writing one or more waveguides in a glass substrate with use of a laser; and creating one or more curved mirrors in the glass substrate to collimate light from the one or more waveguides, wherein creating the one or more curved mirrors comprises forming a cavity in the glass substrate using selective laser etching.

Example 31 includes the subject matter of Example 30, and further including flip chip mounting a photonic integrated circuit (PIC) die on a top surface of the glass substrate, wherein the one or more curved mirrors are to direct collimated light from the one or more waveguides towards the PIC die.

Example 32 includes the subject matter of any of Examples 30 and 31, and further including flip chip mounting an electronic integrated circuit (EIC) die on the top surface of the glass substrate.

Example 33 includes the subject matter of any of Examples 30-32, and further including forming a first plurality of through-glass vias and a second plurality of through-glass vias through the glass substrate using selective laser etching, wherein individual through-glass vias of the first plurality of through-glass vias connect a trace on a redistribution layer on a bottom surface of the glass substrate to the PIC die, wherein individual through-glass vias of the second plurality of through-glass vias connect a trace on the redistribution layer on the bottom surface of the glass substrate to the EIC die.

Example 34 includes the subject matter of any of Examples 30-33, and wherein creating the one or more curved mirrors in the glass substrate comprises applying a reflective surface to an interior surface of the cavity.

Example 35 includes the subject matter of any of Examples 30-34, and wherein the reflective surface comprises aluminum or silver.

Example 36 includes the subject matter of any of Examples 30-35, and wherein the reflective surface comprises a dielectric stack.

Example 37 includes the subject matter of any of Examples 30-36, and wherein individual curved mirrors of the one or more curved mirrors are reflective due to total internal reflection.

Example 38 includes the subject matter of any of Examples 30-37, and further including forming an interface in the glass substrate for an optical connector using selective laser etching.

1. An apparatus comprising:
a glass substrate comprising:
one or more waveguides; and
one or more curved mirrors defined in the glass substrate,
wherein individual waveguides of the one or more waveguides are to direct light to individual curved mirrors of the one or more curved mirrors,
wherein individual curved mirrors of the one or more curved mirrors are to collimate light from individual waveguides of the one or more waveguides.

2. The apparatus of claim 1, further comprising a photonic integrated circuit (PIC) die mounted on a top surface of the glass substrate,
wherein individual curved mirrors of the one or more curved mirrors are to direct light from individual waveguides of the one or more waveguides out of the top surface towards the PIC die.

3. The apparatus of claim 2, wherein the PIC die comprises one or more waveguides, the apparatus further comprising an optical insert mounted on the PIC die, wherein the optical insert comprises one or more curved mirrors, wherein individual curved mirrors of the one or more curved mirrors of the optical insert are to focus light collimated by individual curved mirrors of the one or more curved mirrors of the glass substrate to individual waveguides of the one or more waveguides of the PIC die.

4. The apparatus of claim 2, further comprising a plurality of solder bumps that join the glass substrate and the PIC die, wherein individual solder bumps of the plurality of solder bumps electrically couple the glass substrate to the PIC die.

5. The apparatus of claim 4, wherein the glass substrate comprises a plurality of through-glass vias, wherein individual through-glass vias of the plurality of through-glass vias are electrically coupled to individual solder bumps of the plurality of solder bumps.

6. The apparatus of claim 4, further comprising an electronic integrated circuit (EIC) die mounted on the top surface of the glass substrate, further comprising an additional plurality of solder bumps that join the glass substrate and the EIC die, wherein individual solder bumps of the additional plurality of solder bumps electrically couple the glass substrate to the EIC die.

7. The apparatus of claim 6, wherein the glass substrate comprises a plurality of through-glass vias, wherein individual through-glass vias of the plurality of through-glass vias are electrically coupled to individual solder bumps of the additional plurality of solder bumps.

8. The apparatus of claim 2, further comprising a second PIC die mounted on the top surface of the glass substrate,
the glass substrate further comprising a second curved mirror defined in the glass substrate and a third curved mirror defined in the glass substrate,
wherein the second curved mirror is to focus collimated light from the second PIC die to a waveguide of the one or more waveguides of the glass substrate,
wherein the third curved mirror is to collimate light from the waveguide into a beam and direct the beam out of the top surface towards the PIC die.

9. The apparatus of claim 1, further comprising an optical connector, wherein an interface for the optical connector is defined in the glass substrate, wherein the optical connector is mated with the glass substrate.

10. The apparatus of claim 1, further comprising a redistribution layer on a top surface of the glass substrate.

11. The apparatus of claim 1, wherein individual curved mirrors of the one or more curved mirrors defined in the glass substrate comprise a reflective surface.

12. The apparatus of claim 11, wherein the reflective surface of individual curved mirrors of the one or more curved mirrors comprises aluminum or silver.

13. The apparatus of claim 11, wherein the reflective surface of individual curved mirrors of the one or more curved mirrors comprises a dielectric stack.

14. The apparatus of claim 1, wherein individual curved mirrors of the one or more curved mirrors defined in the glass substrate are reflective due to total internal reflection.

15. An apparatus comprising:
a glass substrate comprising:
means for interfacing with an optical connector that comprises one or more optical fibers; and
means for collimating light from the one or more optical fibers.

16. The apparatus of claim 15, wherein the means for collimating light from the one or more optical fibers comprises one or more curved mirrors defined in the glass substrate.

17. The apparatus of claim 15, further comprising a photonic integrated circuit (PIC) die mounted on a top surface of the glass substrate,
wherein the means for collimating light from the one or more optical fibers are to direct collimated light out of the top surface towards the PIC die.

18. The apparatus of claim 17, further comprising a plurality of solder bumps that join the glass substrate and the PIC die, wherein individual solder bumps of the plurality of solder bumps electrically couple the glass substrate to the PIC die.

19. The apparatus of claim 18, further comprising an electronic integrated circuit (EIC) die mounted on the top surface of the glass substrate, further comprising an additional plurality of solder bumps that join the glass substrate and the EIC die, wherein individual solder bumps of the additional plurality of solder bumps electrically couple the glass substrate to the EIC die.

20. The apparatus of claim 19, wherein the glass substrate comprises a plurality of through-glass vias, wherein individual through-glass vias of the plurality of through-glass vias are electrically coupled to individual solder bumps of the additional plurality of solder bumps.

21. The apparatus of claim 17, further comprising a second PIC die mounted on the top surface of the glass substrate,
the glass substrate further comprising means for receiving collimated light from the second PIC die and directing corresponding collimated light to the PIC die.

22. A method comprising:
direct writing one or more waveguides in a glass substrate with use of a laser; and
creating one or more curved mirrors in the glass substrate to collimate light from the one or more waveguides, wherein creating the one or more curved mirrors comprises forming a cavity in the glass substrate using selective laser etching.

23. The method of claim 22, further comprising:
flip chip mounting a photonic integrated circuit (PIC) die on a top surface of the glass substrate, wherein the one or more curved mirrors are to direct collimated light from the one or more waveguides towards the PIC die.

24. The method of claim 23, further comprising:
flip chip mounting an electronic integrated circuit (EIC) die on the top surface of the glass substrate.

25. The method of claim 24, further comprising forming a first plurality of through-glass vias and a second plurality of through-glass vias through the glass substrate using selective laser etching,
wherein individual through-glass vias of the first plurality of through-glass vias connect a trace on a redistribution layer on a bottom surface of the glass substrate to the PIC die,
wherein individual through-glass vias of the second plurality of through-glass vias connect a trace on the redistribution layer on the bottom surface of the glass substrate to the EIC die.
